(19) United States
(12) Patent Application Publication
(10) Pub. No.: US 2010/0121588 A1
(43) Pub. Date: May 13, 2010

(54) Apparatus, system, and method for improving the accuracy of state of health/state of charge battery measurements using data accumulation

(76) Inventors: David Elder, Margate, FL (US); William Weiss, Boca Raton, FL (US)

Correspondence Address: Tangent Law Group, 601 Pennsylvania Avenue, NW, Suite 900, Washington, DC, 20004, US

(21) Appl. No.: 12/461,871

(22) Filed: Aug. 26, 2009

Related U.S. Application Data
(60) Provisional application No. 61/136,307, filed on Aug. 26, 2008.

(51) Int. Cl. G01R 31/36; G01R 35/00

(52) U.S. Cl. 702/63; 702/85

(57) ABSTRACT

A method, system, and computer network for improving the accuracy of state of health/state of charge calculations of a battery product utilizing a battery tracking network communicating with a battery product, providing for the collection and recording of data from the operational environment of the battery product. Transmitting the collected and recorded data from all battery products in the battery tracking network through the battery tracking network to a database system. Storing the data in the database system. Calculating, using a state of charge/state of health algorithm, an estimated state of charge/state of health and comparing the accuracy of the calculation to the data collected. Then adjusting the state of health/state of charge algorithm based on the comparison with the collected data to improve the accuracy of the state of health/state of charge algorithm. The algorithm being adjusted and transmitted to the battery product to aid in calculating and displaying a state of health/state of charge of the battery product based on the adjusted state of health/state of charge algorithm for review by an operator.

### CROSS-REFERENCE TO RELATED APPLICATIONS

This application claims the priority of U.S. provisional patent application 61/136,307, filed Aug. 26, 2008, which is incorporated herein by reference.

### FIELD OF THE INVENTION

The invention relates to a method, article of manufacture, and a system for tracking and monitoring warranty and performance information for batteries and incorporating this data in improved state of health (SOH) and/or state of charge (SOC) calculations, more specifically to a system including at least one of a database, a computer network, a point of sale/point of maintenance device, and an electronics package on a battery product working to store information on the battery and extract information from the battery and incorporate this information into improved SOH or SOC algorithms or methods, which can then be updated on a battery product.

### BACKGROUND OF THE INVENTION

The automotive industry has been one of the leading innovators in the world throughout the last hundred years. As a leader in advanced technologies, automakers have consistently incorporated state of the art technology into the vehicles we drive. From the analog world of the early twentieth century, the automobiles of today have increasingly incorporated high technology electronics to provide enhanced functionality, ease of use, and ease of maintenance.

However, current battery technologies have lagged far behind this modernization curve. Little impetus has been provided to improve battery technologies beyond advancing some of the chemistry and physical properties within the battery. Nonetheless, as the myriad of technological advances have been incorporated into automobiles, the need for reliable electrical power has also increased—and the battery remains at the heart of providing that power. To supply that power in a more reliable fashion, innovative smart batteries and smart multiple battery systems have been or are being developed by automakers and battery manufacturers alike.

One aspect of interest in these smart batteries is measuring the state of health of the battery or state of charge remaining in the battery (SOH or SOC). To do this the smart batteries have sensors for sensing data regarding the battery and battery performance. This data can be used in conjunction with lookup tables or a mathematical algorithm to predict the state of health of the battery or state of charge remaining on the battery. A number of such mathematical expressions and techniques have been used to predict SOC and/or SOH.

The accuracy of these methods, equations, and tables are all based on accuracy of the data used to derive the methods or tables or equations. Therefore, the better the data, the more accurate the model. There exists a further need to provide an onboard programmable component of a smart battery with software that is capable of both receiving data at point of sale and receiving data at point of maintenance while also allowing for communication of this data and data collected during operation to a centralized data network. Additionally, in receiving this data, the network in conjunction with the smart battery will work to accumulate and average variable data and use this data to improve a state of health (SOH) or state of charge (SOC) equation (s), lookup table(s), or method(s) of calculation. In doing this, the system enables a more accurate calculation of SOH/SOC and a better determination for replacement dates for the battery and more accurate durations on battery warranties.

The apparatus includes a battery system in communications with a network tracking system having a battery product, an at least one of electronics module, an at least one sensor, at least one database, an at least one point of sale/point of maintenance device providing communication with the programmable battery product and an initial data input for communicating data to and from the programmable battery product and the electronics module and also communication of data to and from the database and a network receiving, carrying and transmitting data for storage in the database and data and/or instructions for the battery product and within the database. Where data on the battery is collected through the at least one sensor and stored during operation, the data is transmitted through the network to the database, the database accumulates and performs calculations with the data and based on these calculations updates a state of health/state of charge algorithm that is the then transferred back and used to calculate and communicate the state of health/state of charge of the battery product.

The battery product can communicate with the point of sale/point of maintenance device to communicate the data to the network tracking system. The point of sale/point of maintenance device can be located in a network operations center and be a part of a vehicle communications network. The electronics module can be located remotely from the battery product. The electronics module can also be located on the battery product.

The state of charge/state of health algorithm can be a multivariate equation. The state of charge/state of health algorithm can utilizes at least one of a statistical method and a lookup table in providing a calculation for the state of charge/state of health of the battery product. The adjustment of the state of charge/state of health can be done in real time on the battery product. The adjustment of the state of charge/state of health can also be done with region specific tags to account for region specific environmental conditions or product specific tags to account for product specifications. The data stored can include a description tag of any failures or abnormal parameters measured by the battery with appropriate identifying tags for storage in the database.

The method of the instant invention includes a method of improving the accuracy of state of health/state of charge calculations of a battery product utilizing a computerized battery tracking network communicating with a battery product. The method having the steps of collecting and recording data from the operational environment of the battery product; transmitting the collected and recorded data from all battery products in the computerized battery tracking network through the computerized battery tracking network to a database system; storing the data in the database system; calculating using a state of charge/state of health algorithm an estimated state of charge/state of health and comparing the accuracy of the calculation to the data collected or a calculation derived from the data collected; adjusting the state of health/state of charge algorithm based on the collected data to improve the accuracy of the state of health/state of charge algorithm; transmitting the adjusted state of health/state of charge algorithm or a map from the adjusted state of health/state of charge algorithm to the battery product; and calculating and displaying a state of health/state of charge of the battery product based on the adjusted state of health/state of charge algorithm for review by an operator.

The method step of recording the data can further comprise communicating and recording the data on an electronics module. The method step of recording the data can further comprise communicating and recording the data on an electronics module on the battery. The method step of recording the data can further comprise communicating and recording the data on an electronics module detached from the battery. The method step of collecting data can further comprise coupling the battery product to a point of sale/point of maintenance device.

The method can include a further step of coupling the battery product to a point of sale/point of maintenance device and can further comprise coupling the battery product to a point of sale/point of maintenance device that is in wireless communication with the programmable battery product. The method can also further include the step of coupling the battery product to a point of sale/point of maintenance device further comprises coupling the battery product wirelessly to a CAN/LIN network in communication with a point of sale/point of maintenance device.

The apparatus of the invention includes a computer system executing programmed code for a method of improving the accuracy of state of health/state of charge calculations of a battery product utilizing a computerized battery tracking network communicating with the computer system, the computer system collecting and recording data from the operational environment of a battery product on the computer system. Transmitting the collected and recorded data from all battery products in the computerized battery tracking network through the computerized battery tracking network to a database system in communication with the computer system. Storing the data in the database system and calculating using a state of charge/state of health algorithm an estimated state of charge/state of health and comparing the accuracy of the calculation to the data collected or a calculation derived from the data collected with the computer system. And then adjusting the state of health/state of charge algorithm based on the comparison of the calculation or calculation derived from the collected data to improve the accuracy of the state of health/state of charge algorithm with the computer system and transmitting the adjusted state of health/state of charge algorithm or a map from the adjusted state of health/state of charge algorithm to the battery product. The system then calculating and displaying a state of health/state of charge of the battery product based on the adjusted state of health/state of charge algorithm for review by an operator.

The computer system can also include an electronics module and communicate and record the data on the electronics module. The electronics module can be on the battery. The electronics module can be detached from the battery. The computer system can further include a point of sale/point of maintenance device coupling to the battery product to collect the data. The battery product can also couple to the point of sale/point of maintenance device through wireless communication with the battery. The coupling of the battery product to a point of sale/point of maintenance device can further comprise coupling the battery product wirelessly to a CAN/LIN network in communication with a point of sale/point of maintenance device.

Moreover, the above objects and advantages of the invention are illustrative, and not exhaustive, of those which can be achieved by the invention. Thus, these and other objects and advantages of the invention will be apparent from the description herein, both as embodied herein and as modified in view of any variations which will be apparent to those skilled in the art.

### BRIEF DESCRIPTION OF THE DRAWINGS

Embodiments of the invention are explained in greater detail by way of the drawings, where the same reference numerals refer to the same features.

FIG. 1 illustrates a plan view of the instant invention.

FIG. 2 illustrates a flow diagram of the instant invention.

FIG. 3 illustrates program modules in an exemplary embodiment.

### DETAILED DESCRIPTION OF THE INVENTION

In describing the invention, the following definitions are applicable throughout.

A “computer” refers to any apparatus that is capable of accepting a structured input, processing the structured input according to prescribed rules, and producing results of the processing as output. Examples of a computer include: a computer; a general purpose computer; a supercomputer; a mainframe; a super mini-computer; a mini-computer; a workstation; a micro-computer; a server; an interactive television; a hybrid combination of a computer and an interactive television; a controller processor; an ASIC; and application-specific hardware to emulate a computer and/or software. A computer can have a single processor or multiple processors, which can operate in parallel and/or not in parallel. A computer also refers to two or more computers connected together via a network for transmitting or receiving information between the computers. An example of such a computer includes a distributed computer system for processing information via computers linked by a network.

A “computer-readable medium” refers to any storage device used for storing data accessible by a computer. Examples of a computer-readable medium include: a magnetic hard disk; a floppy disk; an optical disk, such as a CD-ROM and a DVD; a magnetic tape; a memory chip; and a carrier wave used to carry computer-readable electronic data, such as those used in transmitting and receiving e-mail or in accessing a network, such as the Internet or a local area network (“LAN”); or a Bluetooth enabled network and any storage device used for storing data accessible by a computer including for instance hand-held devices or a hard drive disk.

A “computer system” refers to a system having a computer, where the computer comprises at least one computer and a computer-readable medium embodying software to operate the computer.

A “database” is a combination of software and hardware used to efficiently store data on an at least one information storage device, in an exemplary embodiment this includes storage on an information storage device comprising an at least one computer readable medium as defined herein.

A “handheld device” is a handheld device capable of receiving and processing data in a manner emulating a computer as defined herein.

An “information storage device” refers to an article of manufacture used to store information. An information storage device has different forms, for example, paper form and electronic form. In paper form, the information storage device includes paper printed with the information. In electronic form, the information storage device includes a computer-readable medium storing the information as software, for example, as data.

A “network” refers to a number of computers and associated devices that are connected by communication facilities. A network involves permanent connections such as cables or temporary connections such as those made through telephone or other communication links. In this way the network can be maintained by conventional wires or may also be provided wirelessly. Examples of a network include: an internet, such as the Internet; an intranet; a local area network (LAN); a wide area network (WAN); CAN and LIN networks; cellular networks; and any combination of networks, such as an internet and an intranet.

A “point of sale/point of maintenance device” refers to a network interface, a computer or handheld device that is used to interface with a network, a database, and/or with the electronics module of the battery product. This may be a single device or may be comprised of numerous component devices, such as a handheld device used in conjunction with a wireless network connection to a computer which then communicates with a network and, thereby, a database. The point of sale/point of maintenance device is typically located at the point of sale or point of maintenance or manufacture.

A “battery product” refers to a battery or power source independent of electrochemistry, type, or structure and as both as a singular element and as a pack or stick of elements that provide power, it includes single and multiple battery systems as well as multiple battery packs. It can be programmable or non-programmable based on the system.

“Software” refers to prescribed rules to operate a computer or similar device. Examples of software include: software; code segments; program modules; instructions; computer programs; and programmed logic.

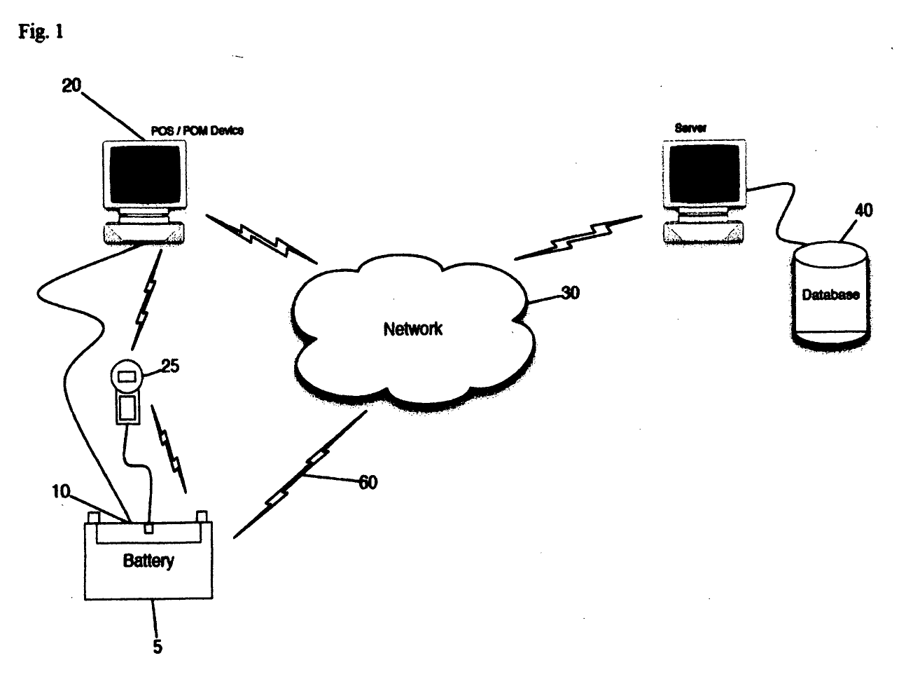

FIG. 1 shows a plan view of the instant invention. The instant invention is directed to a battery warranty and metrics tracking network with a programmable battery product also capable of storing performance data with an information storage device within an electronics module. Sensors within the battery product or the vehicle measure battery data such as, but certainly not limited to, voltage, current, and temperature and transmit the battery data to a control and collection unit within an electronics module. The electronics module receives, processes, analyzes, and stores the battery data. Software running for instance on the electronics module, in the vehicle or on the network monitors and estimates the state of health or state of charge of the programmable battery product and can be configured to provide warning alarms when the battery data is outside preset limits. This data is stored and transferred to a database. The database accumulates the information and in turn modifies the parameters used by the software to calculate state of health or state of charge. The software on the battery is updated regularly via a network, for instance during maintenance or through a CAN/LIN network. The software being updated to make it more accurately estimate, predict or both estimate real time SOH/SOC and predict in the future the state of health or state of charge of the battery product.

With respect to the instant invention, the calculation of the SOH/SOC estimate through an algorithm is a non-trivial element of the invention. However, the wide array of methodologies for making this calculation and the secrecy surrounding the variables in many instances does not allow for an easy or concise listing of parameters used in these multivariate equations. Moreover, a full disclosure or understanding of the intricacies of these highly complex calculations is not needed to fully understand and embrace the usefulness of the instant invention as it relates to these calculations. Batteries are highly non-linear devices and many processes with different time constants are overlapping. Therefore, linear model approaches typically fail. The evaluation of the battery state variables is complex even if the measured data are available with high precision and reliability. Battery manufacturers typically give no details on their algorithms, but several scientific papers are published on these issues. As such the following basic description is provided of what the SOH/SOC algorithm is calculating. One or ordinary skill in the art would understand that the description provided herein is simplified and that a more robust calculation is both needed and can be provided in the instant invention while fully utilizing and realizing the advantages of the inventions method of improving such a calculation.

The SOC or state of charge of the battery is the amount of charge that can be discharged from the battery at a nominal current. For example, if the battery is flat this means that the battery has a low state of charge, if the battery is full this means that the battery has a high state of charge. Mathematically then:

SOC=Qn/Cn rated

This means that the SOC is a ratio of the rated charge capacity of the battery versus the current nominal capacity. Several variables can affect SOC and SOH, for example the ambient temperature of the battery as well as the discharge rate can directly affect the SOC. Using the SOC/SOH algorithms to calculate the SOC is common practice in battery monitoring systems however these algorithms use both averaged as well as assumed values in the mathematical equation. The averaged and assumed values are used due to the fact that batteries operate in a variety of different conditions. These values thus have an effect on the accuracy of the calculated SOC or SOH. It is important to accurately predict the SOC and SOH as this is the early warning notice to the operator of the vehicle containing the battery, ensuring that the operator of the vehicle or a vehicle network advisor has sufficient notice of a pending failure. By continuously monitoring and recording the parameters of the operational conditions of the battery in its geographical and environmental conditions more precise data can be collected on the response of the battery to these conditions and by accumulating and using this accumulated data a more accurate calculation can be made for all batteries in the network.

Similarly the SOH State of Health of the battery is a measure of capacity (C actual) is compared with a rated capacity (C rated), capacity is also referred to as charge storage capability. That is the amount of charge that can be discharged with a nominal current from a fully charged battery at a specific temperature. The SOH is a ratio of the rated capacity versus the actual capacity of the battery at time of testing. Mathematically, this can be shown as:

SOH=Cn actual/Cn rated

The test for SOH is typically done by discharging a fully charged battery with a nominal current to a pre-determined voltage level. This however cannot be performed during the normal operation of the battery in situe. Using algorithms to calculate the SOH is common practice in battery monitoring systems, however these algorithms use both averaged as well as assumed values in the mathematical equation. The averaged and assumed values are used due to the fact that batteries operate in a variety of different conditions. These values thus have an effect on the accuracy of the calculated SOC or SOH. Again, it is important to accurately predict the SOC and SOH as this is the early warning notice to the operator of the vehicle containing the battery, ensuring that the operator of the vehicle has sufficient notice of a pending failure. The instant invention would, by continuously monitoring and recording the parameters of the operational conditions of the battery in its geographical and environmental conditions, provide a more precise calculation of SOC/SOH and allow for the response of the battery to these operating conditions.

The above descriptions are simplified and represent the broadest description of the calculation enumerated in the instant invention. The following are only a small sampling of examples of the wide range of possible approaches to performing SOC/SOH calculations listed here as only as a component of the broadest aspects of the invention. Regardless of the model, the use of aggregate data across a large network accumulating data across a wide spectrum of operating conditions and units will improve any of these methodologies. The comparison in real time of the data from the distributed network of battery products will have an immediate and comparable effect on the calculations of the SOC/SOH that can be measured and evaluated.

Some non-limiting examples of parameters, measurements and mathematical computations strategies are listed here. For example, current integration: requires a precise measurement of the battery current during standstill as well as during cranking. Integration of errors due to incomplete correction for internal Ah losses e.g. due to gassing or measurement errors requires frequent correction of the Ah balance. Current integration is a prerequisite for almost all successful algorithms used today. The latest generation of current sensors allows for highly accurate measurements and incorporation of these variables in SOH/SOC calculations. By measuring these variables in real time and storing and transmitting same, the instant invention would provide for a large sample distribution, recordation, and correction of any calculation made using these parameters.

Other measurement of the equilibrium voltage during open circuit conditions: can be used only during stand-still periods, depending on the battery technology it can take a very long time until the equilibrium potential is available, acid stratification especially in flooded lead-acid batteries leads to misleading voltage measurements, some battery technologies show little gradients in the open circuit voltage as a function of depth of discharge and therefore evaluation errors appear to be large. SOC/SOH calculations can include variables accounting for this.

Similarly, there are several measurement techniques for impedance. Different concepts are used which either measure the frequency response in wide frequency ranges or at selected frequencies; for the analysis either the real part, the imaginary part, the phase angle or other impedance information are used; impedance might be measured using available noise in the power net or by using active excitation. The selection and results of these vary with regard to several operational environment conditions. The use of the instant invention would allow for accumulation across a large number of samples and provide for more accurate assessment of such measurements for incorporation in a resulting algorithm.

Likewise, battery models at different level of complexity are used to evaluate internal parameters of the battery, which cannot be measured directly, that is they extrapolate from the available data on current, voltage and temperature or impedance. Today mainly a combination of mathematical and physics bases models are used. The internal parameters of the model must be adapted accordingly for the battery and a wide range of variables including for instance the type of battery in use and the age of the battery. One successful method utilizes Kalman filters. However, real physical-chemical models typically exceed the capacity of the controller platforms on a battery, but can be used in conjunction with a battery tracking network of the type suggested herein. The capacity for calculations and modeling would be less limited as the modeling could be done in real time within the network and the results could be utilized at the vehicle. For instance the system can simply transmit an updated map based on the algorithms to the battery.

In similar fashion, monitoring of the battery and adapting self-learning algorithms of maps including continuous observation of the battery performance and appropriate storing of the data have been used to show changes in the battery behavior as a result of aging or general operating conditions, with most information is delivered by analyzing the starting pulse. However, the data has never been accumulated, utilized and updated through a real time network with the ability to adjust for given parameters unique to a region, location, age, product type or similar battery variables.

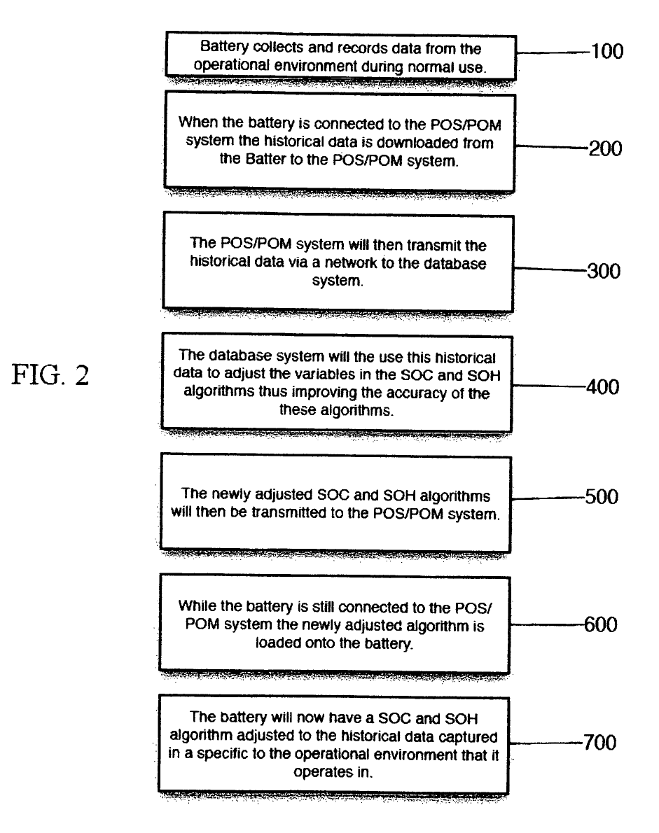

The components of the system include at least one of an onboard electronics module 10 on a programmable battery product 5; sensors or telesensors 13, a point of sale/point of maintenance device 20, which can be for instance a handheld device or a stationary device having similar characteristics, the device 20 providing communication with the programmable battery product 5 and an initial data input for communicating data to and from the battery 25 and electronics module 10 and also communication of this data to and from a product database 40; and a network 30 carrying relevant data for storage in the product database 40 and data and/or instructions 50 for storage on the programmable battery product 5 and within the database 40. Reference to a network, a database, an information storage device, a point of sale/point of maintenance device, and an electronics module is to be read as including at least one of each device that is reference to the singular includes all derivations of the plural for each feature disclosed. For example, with respect to the use of the term network, the invention can use the internet at the initial point of sale or maintenance and can also utilize an existing CAN/LIN network, as shown in FIG. 2 network communications link 60 during operation to update data both to and from the battery where the point of sale/point of maintenance device may be part of the CAN/LIN network or a vehicle communications network.

The electronics module 10, the point of sale/point of maintenance device 20, network 30, and database 40 further includes at least one computer-readable medium in an information storage device embodying software for implementing the invention and/or software to operate the electronics module 10, the point of sale/point of maintenance device 20, the network 30, and database 40 in accordance with the invention. Furthermore, the programmable battery product 5 may be any battery capable of accommodating the electronics module 10. In an exemplary embodiment the programmable battery product 5 is a smart battery or multiple battery system having an at least one electronics module 10 thereon. Additionally, a version of the instant invention may include a separate after market version that exists externally to the battery with the required electronics module and sensors attached to the battery.

The sensors in the system measure battery data such as voltage, current, remaining battery capacity, remaining battery charge, resistivity, capacitance, temperature and the like and transmit the battery data to the electronics module 10 for collection. The electronics module 10 receives, processes, analyzes, and stores the battery data using the software contained thereon. Software running on the electronics module 10 monitors and estimates the state of health or state of charge of the battery and can be configured to provide warning alarms when the battery data is outside present limits. In an exemplary embodiment, the point of sale/point of maintenance device 20 or the programmable battery product 5 would operate as a distributed network connected to servers for data storage and retrieval nationwide.

The software operating the exemplary embodiment of the invention can include for example operating software for the electronics module, the point of sale/point of service devices, communications protocols, and the like, hereinafter referred to program modules. The software functions in conjunction with the hardware including an at least one controller or computer enabling execution of the programming contained in the software. FIG. 2 describes the process flow of the instant invention. During the normal operation of the battery 5 and/or electronics module 10 in situe it will collect and record parameters of operation, for instance but not limited to ambient temperature, charge rate, discharge rate, frequency of use, and the like, of the battery 5 in the operational environment as shown in 100. When the battery is connected to a point of sale or point of maintenance system 20 via a network as described, for example when the vehicle goes in for service the data recorded by battery 10 is downloaded from the battery to the POS/POM system 20 as described in 200. The POS/POM system 20 will then transmit this data via a network 30 to the data base 40 as described in 300. The database system 40 will then adjust the variables in the SOC/SOH algorithms to improve the accuracy of these algorithms as described in 400. The newly adjusted algorithms for SOC/SOH will then be transmitted from the database 40 via the network 30 to the POS/POM system 20 or the battery 5 as described in 500. While the battery 10 is still connected to the POS/POM system 20 the newly adjusted algorithms will then be downloaded from the POS/POM system to the Battery 5 as described in 600. The battery 5 can now be retuned to service in its normal operating environment. Due to the fact that the battery now contains the algorithms that have been adjusted to better fit the historical data recorded in the operational environment the resulting preemptive alerts and information provided to the user or operator will be more accurate. The electronics module 10 of the exemplary embodiment has a computer or processor or equivalent hardware for executing the method of the instant invention. The program modules make up elements of the software and function together to provide tracking of specific information about individual battery products 5. Each module can function independently of the others and there is no specific order of operation, however, in an exemplary embodiment of the instant invention the software embodying the invention is loaded throughout the network 30 into the point of sale/point of maintenance devices 20 for distribution into the programmable battery product 5.

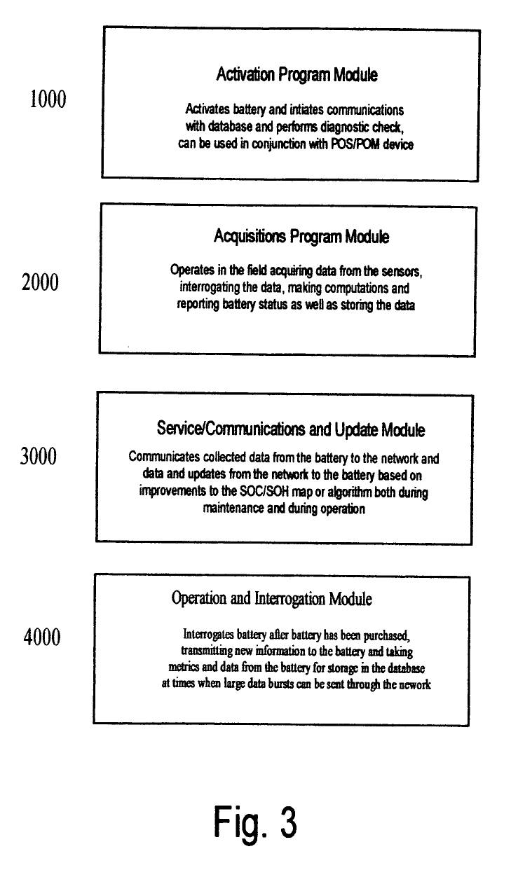

FIG. 3 illustrates program modules in an exemplary embodiment. In the exemplary embodiment, these modules include at least one of an activation module, an acquisition module, and a service communication and update module. During the initial sale of the battery product, the first program module or activation module 1000 is activated through the point of sale/point of maintenance device 20 to program the programmable battery product 5. The programmable battery product 5 is activated by the point of sale/point of maintenance device 20 activating the electronic module 10, which runs a diagnostic check of the battery and then allows for entry of sales specific programming, activation, configuration information for the programmable battery product 5 and similar data acquisition, reporting and entry. The second program module or acquisition module 2000 operates in the field acquiring data from the sensors, interrogating the data, making computations and reporting battery status as well as storing this data. A third module or service/communication and update module 3000 communicates information from the battery and to the battery during operation. The service communication and update module then updates the SOC and/or SOH and other software on the battery product.

The software modules form a tracking system for the exemplary embodiment of the programmable battery product 5. The tracking system stores “tags” or data specific to identifying the battery as well as operational data. These tags or data specific to identifying the battery can include for example an “in-service” date, installation date, calendar life, a last serviced date, sales/installation location information, storage location information, gps data, owner identifying information, zip code, region specific data tags, related region specific data such as average temperature, mean temperature, average humidity, mean humidity, voltage, amp hours, amp hours used, conductivity, resistivity, remaining charge, remaining battery capacity, capacitance, and the like. At the same time, the “smart” or programmable battery product can store performance data in real time for the battery while in operation. This data can include, but is certainly not limited to, metrics regarding any of the characteristics of the battery, including for example voltage, amps, temperature, and similar characteristics as well as vehicle data communicated from the vehicle to the battery and event specific data. This data is then accumulated on the network 30 and these data points are utilized in updates to software on the programmable battery product 5, as outlined below.

In this first program module or activation module, the system software allows for programming, activation, and configuration of the programmable battery product 5. The programmable battery product 5 may be any battery capable of accommodating the electronics module 10. The activation module 1000 wakes the programmable battery product 5 from its storage mode. The activation module 1000 activates the electronics module 10 in a transmitting step by transmitting a code from the point of sale point of maintenance device to the electronics module. The activation module 1000 then looks for software updates from the point of sale/point of maintenance device or through the network 30 from the product database 40 and performs an initial update step, updating the software on the electronics module 10. The latest software for activating and operating the programmable battery product 5 and estimating state of health state of charge is thereby provided via the instant invention from the database 40 through the point of sale/point of maintenance device. Additional embodiments can provide for the pre-loading or installation of this software at the factory and the updating step can be performed later by the update module. In a further program module 4000 operation, the point of sale/point of maintenance device 20 is used during installation or maintenance or at a location where the programmable battery product 5 is being returned to interrogate the information regarding the programmable battery product 5 stored in the electronics module 10.

In addition to an updating step, the activation module includes a data entry step, whereby certain identifying information and region specific data, such as regional data tags are entered via the point of sale/point of maintenance device onto the battery. This can be accomplished via any input device, non-limiting examples being a keyboard or touch screen. This data is then communicated in an initial communication step to the database 40. These data tags or data specific to identifying the battery can include, for example, but are certainly not limited to, identification of the point of sale, the date of purchase, a level of warranty, a time period of warranty, an “in-service” date, a last serviced date, sales/installation location information, vehicle identifying information such as VIN number, vehicle make and model information, locale and geographic specific information, storage location information, gps data, regional information, vehicle specific/manufacturer specific information, and other relevant information, owner identifying information, zip code, region specific data tags, related region specific data such as average temperature, mean temperature, average humidity, mean humidity, and the like. This information, in portions or in its entirety, is stored on the programmable battery product 5 and within the database 40.

A further activation step provides for activation of additional programmable capabilities on the programmable battery product 5. In instances where the programmable battery product 5 has multiple programmable configurations, the specific configuration can be activated via the point of sale/point of maintenance device 20. Software is pushed into the electronic package 5 and relevant hardware components and accessory function onboard the battery can be selectively enabled based on this software. One example of such a multiple configuration intelligent battery system or programmable battery product is applicant's INTELLICELL battery system, which can be configured for multiple feature levels as well as vehicle and geographic specific functionality. These can include, for example, but certainly are not limited to, activating specific feature rich hardware onboard the intelligent battery system, such as, but certainly not limited to, the hardware indicated in applicants co-pending U.S. patent application Ser. Nos. 10/604,703, 10/708,739 and 10/913,334, herein incorporated by reference. The second or acquisition module is used during the operation of the programmable battery product 5 after it is activated and installed and receives its initial programming. In a monitoring step the electronics module 5, in conjunction with the sensors 13, monitors performance data for the programmable battery product 5. This performance data from the programmable battery product 5 is collected and stored in a memory device in a storage step. This data can include metrics regarding any of the characteristics of the battery, including for example, but certainly not limited to, voltage, amps, temperature, and similar characteristics as well as vehicle data communicated from the vehicle to the battery and event specific data that is stored based on previously stored event parameter data pushed onto the programmable battery product 5. This data is then used in a calculation step, calculating the SOH or SOC of the battery for example. The results of the calculating step can then be displayed in a display step or compared to stored parameters and alert sent in a comparison step if the data is outside the parameters via the communication and updating module. The alert may be sent to a user via an alert or user interface. An alert may be transmitted for instance via an alert mechanism, for instance a klaxon, buzzer, key fob with an LED or similar indicator, or devices that can function in a similar fashion to provide a visual or audible alert to a user. Additionally or alternatively, an alert may be communicated via a network to a Network Operations Center (NOC) for analysis and response.

Additionally, the acquisition module may include a predictive calculation element. In the predictive calculation element, based on the stored data and data collected during operation the useful life of the battery or the battery charge is estimated. This prediction can be communicated to the user via a user interface, for instance in a vehicle user interface. Alternatively or additionally, it may be communicated to a NOC to facilitate regular maintenance reports for replacement of the battery or to indicate the estimated overall power left in a vehicle, particularly in an electric or hybrid electric vehicle battery pack.

A communication module periodically transmits the stored data or data tags from the programmable battery product 5 through the network 30 to the database 40. The collected data on the database 40 can then be analyzed by computers within the network. The analyzed data within the database 40 can then be used to modify the existing methods, equations, lookup tables, and software used to calculate SOH and SOC on the battery products 5. For instance, this accumulated data can be averaged for specific variables like mean temperature, humidity or other variables for a region, a zip code, a city or the like. Other variables and methodologies can make use of the large sample size and accumulated data to extract specific variables or make correlations that may then be used to improve the existing methods, equations, lookup tables, software or the like used to estimate an SOH/SOC. For example, in the case of equations using mean temperature and humidity, the accumulated data averages or means can thereby be used to adjust an equation utilizing these variables on the programmable battery product 5. With a much larger sample size, these averages, means and accumulated variables in general are more accurate and would result in a more accurate SOH/SOC estimation. These revised methods, equations, lookup tables, and software can then be pushed back through the network 30 to all fielded battery products 5 by calls from the communications module or from software on the network. These averages can be updated regularly through the network, either in real time or at a set interval or at a specified service date or maintenance visits. Additionally, the information stored on the database 40 may then be compared to the stored data within the database 40 during maintenance or to verify warranty claims.

In the exemplary embodiment shown the program modules that function together as the system software that provides tracking of specific information about the individual battery products. Each module can function independently of the others and there is no specific order of operation, however, in an exemplary embodiment of the instant invention the software embodying the invention is loaded throughout the network 30 into the point of sale/point of maintenance devices 20 before beginning operation. In this exemplary embodiment, during the initial sale of the battery product, the first program module or activation module 1000 is activated through the point of sale/point of maintenance device 20 to program the programmable battery product 5 or directly to the programmable battery product 5. The programmable battery product 5 is activated by the point of sale/point of maintenance device 20 activating the electronic module 10, which runs a diagnostic check of the battery and then allows for entry of sales specific programming, activation, and configuration information for the programmable battery product 5, as noted. The activation module 1000 looks for software updates, which can be pushed from the database 40 to the point of sale/point of maintenance devices 20 for installation of the latest software in the programmable battery product 5. The acquisition module then collects the operational data from the battery and stores it along with other information, such as events or situations where variables go below specific thresholds and sends alerts. The communication module then communicates this data back to the database and the updating function of the module updates the software on the battery module. With the exception of the activation module, the frequency, order, and timing of these operations are independent in the embodiment.

This data warehousing on the database 40 provides manufacturers and distributors with heretofore unknown tracking and metrics capabilities. The data warehousing within the battery warranty and metrics tracking system allows distributors and manufacturers to analyze the data fields in the database 40 and make determinations and correlations regarding battery costs and performance and thereby adjust SOH and SOC methods, equations, tables and the like, as well as warranties, accordingly. The data warehousing also enables faster recall notifications for potential service issues. Additionally, the data enables manufacturers to more clearly fit and enforce warranties based on regional zones and provides enhanced tracking for warranty claims, including data on metrics. This metrics tracking would provide for faster improvements in designs based on this data. For example, if warranty hits increased or maintenance data showed increased failures in cold weather regions, battery design could be more efficiently adjusted to improve cold weather performance.

In addition to storing the data during operation, if at any point in time the battery becomes inoperable, the data received prior to it being rendered into this inoperable state can be stored and categorized. The data can be stored as a failure mode or failure tag result. These failures, if readable by the electronics hardware, can be immediately identified and tagged as one of the following “failure modes” as defined by BCI (Battery Council International):

| | |
|---|---|
| SERVICEABLE | SERVICE AND CHARGE |
| | DISCHARGED ONLY |
| | LOW CAPACITY |
| WORN OUT/ABUSED | OVERCHARGED AND/OR ABUSED |
| | UNDERCHARGED (IRREVERSIBLE SULFATION) |
| | LOW ELECTROLYTE LEVELS (*visual inspection and data entry as noted below) |
| | SEVERE TERMINAL CORROSION (*visual inspection and data entry as noted below) |
| | VIBRATION(*visual inspection and data entry as noted below) |
| | WORN OUT |
| | RECHARGED IN REVERSE |
| | FROZEN |
| | HYDRATION DUE TO LOW ELECTROLYTE LEVELS (*visual inspection and data entry as noted below) |
| BROKEN//DAMAGED | DAMAGED CONTAINER (*visual inspection and data entry as noted below) |
| | DAMAGED COVER (*visual inspection and data entry as noted below) |
| | DAMAGED TERMINAL - EXTERNAL (*visual inspection and data entry as noted below) |
| | INTERNAL DAMAGE (*visual inspection and data entry as noted below) |
| | CONTAINER/COVER SEAL LEAKAGE (*visual inspection and data entry as noted below) |
| | TERMINAL LEAKAGE - S/T (*visual inspection and data entry as noted below) |
| | TERMINAL LEAKAGE - TOP (*visual inspection and data entry as noted below) |
| OPEN CIRCUIT | OPEN CIRCUIT - CELL TO CELL |
| | OPEN CIRCUIT- BROKEN STRAP |
| | OPEN CIRCUIT - CELL TO TERMINAL |
| SHORT CIRCUIT | SHORT CIRCUIT - PLATE TO STRAP |
| | SHORT CIRCUIT - PLATE TO PLATE (PLATE FAULT) |
| | SHORT CIRCUIT - PLATE TO PLATE (SEPARATOR FAULT) |
| | SHORT CIRCUIT - PLATE TO PLATE (SEDIMENT FAULT) |
| | SHORT CIRCUIT - PLATE TO PLATE (HYDRATION) |
| | SHORT CIRCUIT - PLATE TO PLATE (GLUE) |
| PLATES//GRIDS | GRID CORROSION (*visual inspection and data entry as noted below) |
| | PASTE ADHESION (*visual inspection and data entry as noted below) |
| | NEGATIVE MATERIAL SHRINKAGE (*visual inspection and data entry as noted below) |
| | SOFT POSITIVE MATERIAL (*visual inspection and data entry as noted below) |
| | SULFATION(*visual inspection and data entry as noted below) |
| | CORRODED LUGS//STRAPS (LUG ROT) (*visual inspection and data entry as noted below) |
| | NEGATIVE SOFT, PUFFY (*visual inspection and data entry as noted below) |
| ASSEMBLY | DROPPED/LOOSE PLATES (*visual inspection and data entry as noted below) |
| | REVERSED - WRONG COVER (*visual inspection and data entry as noted below) |
| | REVERSED ASSEMBLY (INTERNAL) (*visual inspection and data entry as noted below) |
| | REVERSED CELL(S) (*visual inspection and data entry as noted below) |
| FORMATION | REVERSED FORMATION |

The majority of the failure modes can be identified by the onboard hardware (those noted in bold for example). Those failure modes that cannot be identified via the hardware can be identified through a visual inspection and the findings may be manually entered into the data base, for instance via the point of sale/point of maintenance device. This in turn allows for simultaneous tracking of warranty data information and can be utilized in conjunction with a warranty tracking system such as that of applicants co-pending warranty tracking system.

Additionally, as the predictive module estimates that the programmable battery product is approaching the end of the useful life of the programmable battery product 5 or an imminent battery failure is detected on the programmable battery product 5, data stored on the battery is more frequently updated. Portions of this data can be used to analyze the performance of the electrochemical makeup of the battery and its performance relative thereto in addition to the previously discussed data. This data can be used to update the electrochemistry of the current batteries by transmitting the performance data back to the OEM for analysis and adjusting the electrochemistry to adjust for the shortcomings found in the data. The method for performing such adjustments includes activating the battery within the network as described above. Operating the battery and estimating an end of useful life. Storing specific electrochemical related data and transmitting the same to be used in changing the electrochemical makeup of future batteries under manufacture.

The embodiments and examples discussed herein are non-limiting examples. The invention is described in detail with respect to exemplary embodiments, and it will now be apparent from the foregoing to those skilled in the art that changes and modifications may be made without departing from the invention in its broader aspects, and the invention, therefore, as defined in the claims is intended to cover all such changes and modifications as fall within the true spirit of the invention.

1-14. (canceled)

15. An electronically controlled actuator and at least one valve in a plumbed water line within a water conditioning management system, comprising:
an at least one valve having at least two operating positions besides closed or off with a valve stem in a plumbed water line within the water conditioning management system wherein the valve has an at least one water input and an at least two water outputs;
an at least one actuator;
an at least one actuator housing;
an at least one electronic controller in communication with the actuator wherein said controller activates the actuator to turn the electronically controlled actuator within the plumbed water line within the water conditioning management system, and thereby the valve, based on an input from an at least one control input from the water conditioning management system to one of the at least two operating positions to incrementally redirect water in the water conditioning management system between at least a first of the at least two water outputs and a second of the at least two water outputs, where the redirected water is conditioned by the water conditioning management system;
an at least one shaft coupled to the actuator and said valve;
an at least one shaft encoding device; and
an at least one user interface with multiple indicator elements indicating the position of the valve and any incremental changes of this position, there being a programmed safety point defining a safe area for operation of the valve as indicated by the indicator elements and including a warning indicator as part of the at least one user interface, the warning indicator indicating the passage of the valve during operation of the actuator to move out of the safe zone with an override input which must be pressed to move the actuator and thereby the valve beyond the at least one set point defining the safe zone.

16. (canceled)

17. The electronically controlled actuator in a plumbed water line of claim 15, wherein the multiple indicator elements indicating the position of the valve are LEDs.

18. The electronically controlled actuator in a plumbed water line of claim 17, wherein the LEDs are arranged in a circle and triggered to light upon the passing of the valve through a designated position.

19. The electronically controlled actuator in a plumbed water line of claim 15, wherein the at least one user interface further comprises an at least one manual input for adjusting the at least one valve.

20. The electronically controlled actuator in a plumbed water line of claim 19, wherein the at least one manual input further comprises two manual inputs one associated with manual clockwise and the other associated with manual counterclockwise operation of the valve.

21. The electronically controlled actuator in a plumbed water line of claim 15, wherein the at least one user interface further comprises an at least one set point indicator.

22. The electronically controlled actuator in a plumbed water line of claim 15, wherein the housing further comprises a first housing component, a second housing component and a chassis, the first housing component being coupled to the second housing component and the chassis being held therebetween, the housing further containing the controller and the actuator and being releasably sealed and watertight.

23-34. (canceled)
